(19) United States
(12) Patent Application Publication
(10) Pub. No.: US 2023/0327553 A1
(43) Pub. Date: Oct. 12, 2023

(54) POWER MODULE FORMED WITH A SWITCH-MODE POST-REGULATOR TO PROVIDE A HIGH SLEW RATE PULSED OUTPUT CURRENT AND/OR VOLTAGE

(71) Applicant: Astrodyne TDI, Hackettstown, NJ (US)

(72) Inventors: Gary J. Mulcahy, Flanders, NJ (US); Chris Hewitt, Stroudsburg, PA (US)

(73) Assignee: Astrodyne TDI, Hackettstown, NJ (US)

(21) Appl. No.: 18/160,622

(22) Filed: Jan. 27, 2023

Related U.S. Application Data
(60) Provisional application No. 63/303,567, filed on Jan. 27, 2022.

(51) Int. Cl. H02M 3/158; H02M 1/00

(52) U.S. Cl. CPC H02M 3/158; H02M 1/0029

(57) ABSTRACT

A post regulator for use with a power system including a power converter configured to produce a bus voltage on an output bus. The post regulator includes a transistor circuit coupled to the output bus of the power converter, and further includes a controller configured to receive the bus voltage and control the transistor circuit to alter an output voltage of the post regulator for a period of time to enhance a slew rate of an output current and/or the output voltage of the post regulator from a first level to a second level.

### RELATED APPLICATION

This application claims the benefit of U.S. Provisional Patent Application Ser. No. 63/303,567 filed Jan. 27, 2022, the disclosure of which is incorporated herein by reference.

### FIELD OF THE INVENTION

The present invention is directed in general to power electronics and, more particularly, to a power module operable to provide a high slew-rate, pulsed output current and/or voltage to power a load.

### BACKGROUND

Power systems and modules sometimes operate in an environment that requires an output voltage and current provided by a power converter that can supply a rapidly changing output voltage and/or output current. Powering applications requiring pulsed currents with high slew rates are not well served with conventional off-line alternating current-direct current (“ac-dc”) power converters.

A typical approach for supporting these applications is to utilize a high bandwidth linear post-regulator coupled to an output of an off-line power converter. As introduced herein, a more efficient and reliable alternative to this approach utilizes high frequency switch-mode power conversion techniques.

### SUMMARY

These and other problems are generally solved or circumvented, and technical advantages are generally achieved, by advantageous embodiments of the present invention for constructing a post regulator for use with a power system. The post regulator is coupled to a power converter configured to produce a bus voltage on an output bus. In an embodiment, the post regulator includes a transistor circuit coupled to the output bus of the power converter, and further includes a controller configured to receive the bus voltage and control the transistor circuit to alter an output voltage of the post regulator for a period of time to enhance a slew rate of an output current and/or the output voltage of the post regulator from a first level to a second level.

The foregoing has outlined rather broadly the features and technical advantages of the present invention in order that the detailed description of the invention that follows can be better understood. Additional features and advantages of the invention will be described hereinafter, which form the subject of the claims of the invention. It should be appreciated by those skilled in the art that the conception and specific embodiment disclosed can be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention and the advantages thereof, reference is now made to the following descriptions taken in connection with the accompanying drawings, and which:

FIGS. 1 and 2 illustrate power systems each formed with a power converter coupled to source of electrical power;

FIG. 3 illustrates a simplified circuit representation of portions of an ac-dc power converter with a pulsed output current;

FIG. 4 illustrates graphical representations of an operation of the power converter of FIG. 3;

FIG. 5 illustrates a graphical representation of an example slew rate of an output current and output voltage versus capacitance for an output capacitor of a power converter;

FIG. 6 illustrates a graphical representation demonstrating an increase in slew rate with a voltage boost;

FIG. 7 illustrates a block diagram of an example power system capable of operating from ac input power and delivering a high output voltage with a high current slew rates in support of pulsed dc output currents in either a unipolar or bipolar format;

FIG. 8 illustrates post regulator waveforms produced by a power system during a current pulse in a design for a 1 kHz, pulsed 100 A current delivered from a 60 V source;

FIG. 9 illustrates a simplified schematic drawing of a high-frequency switch-mode power converter designed to support an output with temporary increases in input voltages;

FIG. 10 illustrates a graphical representation that compares hysteretic control with pulse width modulated control;

FIG. 11 illustrates a pulsed ampere output current produced by multiple converters operating in parallel, and a resulting output voltage;

FIG. 12 illustrates a block diagram for an example power system that provides pulsed power with a high output current slew rate;

FIG. 13 illustrates an image of a monolithic implementation for a liquid-cooled input/output unit that supports high output currents; an

FIG. 14 provides an image of an assembly that can be paralleled with other like units to support currents to hundreds of amperes.

Corresponding numerals and symbols in the different figures generally refer to corresponding parts unless otherwise indicated, and cannot be redescribed in the interest of brevity after the first instance. The FIGUREs are drawn to illustrate the relevant aspects of exemplary embodiments.

### DETAILED DESCRIPTION

The making and using of the present exemplary embodiments are discussed in detail below. It should be appreciated, however, that the embodiments provide many applicable inventive concepts that can be embodied in a wide variety of specific contexts. The specific embodiments discussed are merely illustrative of specific ways to make and use the systems, subsystems, and modules associated with a system and method for design of a power system and module operable in an environment that operates with a rapidly changing output current and/or a rapidly changing output voltage.

A system will be described herein with respect to exemplary embodiments in a specific context, namely, a broad class of power systems. The specific embodiments may include, but are not limited to, power systems and modules coupled to an ac or dc input voltage source and provide a dc output voltage with a rapidly changing output current and/or output voltage. The principles of the present invention are applicable to other power system designs operable from an ac or dc input voltage that may provide an ac or dc output voltage.

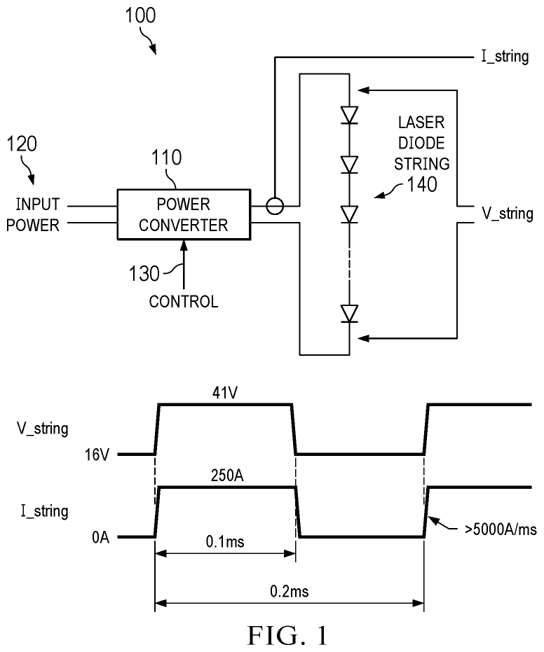

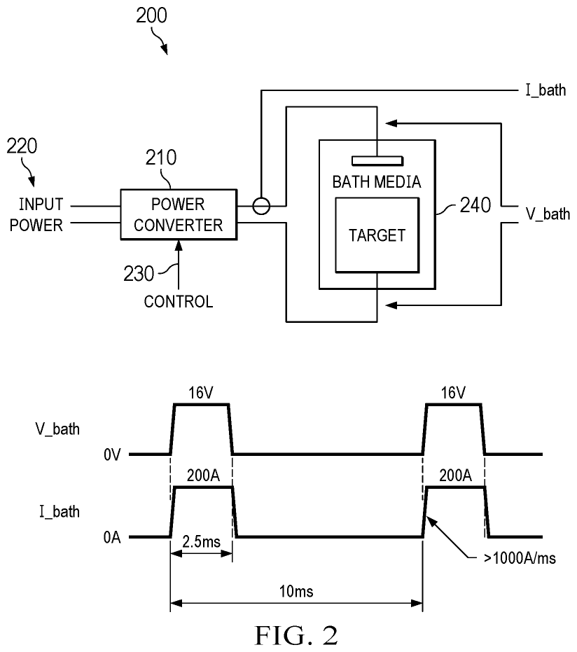

An objective of the disclosure is to provide a power system that converts locally available input electrical power (which is typically ac utility power) into a power type and magnitude more suitable for an end application, which may require pulsed electrical currents at high slew rates (i.e., for example, the amount of time required for the current to transition from a minimum value to a maximum value) and pulse repetition frequencies. Common application examples can provide power for semiconductor lasers with current transition times of the order of one microsecond (“μs”) for a 250 ampere (“A”) pulsed current, as illustrated in FIG. 1, or provide power for a pulsed plating application providing a 200 A pulsed current with a transition time on the order of 10 μs, as illustrated in FIG. 2.

As illustrated in FIG. 1, a power system 100 formed with a power converter 110 is coupled to source of electrical power 120. The power converter 110 is controlled by a control signal 130 and provides pulsed power to a laser diode string 140, as illustrated by the voltage string V_string and the current string I_string. As an example, the power system 100 operates with a switching frequency of five (5) kilohertz (“kHz”), and provides a peak power of 10.25 kilowatts (“kW”), an root-mean-square (“RMS”) power of 7.25 kW, and an average power of 5.13 kW.

Turning now to FIG. 2, illustrated is a power system 200 formed with a power converter 210 coupled to a source of electrical power 220. The power converter 210 is controlled by a control signal 230 and provides pulsed power to an example plating process in a bath medium 240, as illustrated by voltage V_bath and current I_bath. As an example, the power system 200 operates with a switching frequency of 100 kHz, and provides a peak power of 32 kilowatts (“kW”), an RMS power of 16 kW, and an average power of 8 kW.

As illustrated in both of these applications, pulsed currents can require slew rates of 1,000 amperes per millisecond (“A/ms”), 5,000 A/ms or even higher, with currents in the hundreds of amperes. Delivered current in some applications can be unipolar, and sometimes can be bipolar. Common considerations in these types of applications include dealing with power levels of the order of 10's of kilowatts or more, powering processes that demand delivered current slew rates up to 1,000 A/ms or higher, providing a connection between the power converter and the load that can present significant inductance (which limits delivered rate of change of current (di/dt)), and working with off-line power supplies that generally have limited output slew rates.

Commercial ac-dc power supplies are generally designed for the primary task of providing a stable, constant dc output voltage for constant or varying input voltages or output currents. While these commercial ac-dc power supplies support, at some level, varying or pulsed output currents when operating with a constant output voltage, these supplies are typically not able to slew their output voltage quickly enough to force a controlled pulsing current at frequencies by many applications. A main reason for this is impedance limitations of dc output filter capacitors.

In the case of high-frequency switch-mode (“HFSM”) power supplies there are two criteria that set the value of these capacitors. A first criterion is providing a low impedance at the switching frequency to limit output voltage ripple. A second criterion is to provide adequate energy storage to limit output voltage excursions due to energy storage in the output filter inductor upon both application and removal of the load. Given these constraints, output capacitance is generally in the range of 30 to 50 microfarads (“μF”) per ampere of delivered output current. For example, a unit rated to 60 volts (“V”) at 100 amperes (“A”) (6 kW) will typically have around 4,000 μF of output capacitance.

Once an output capacitor is chosen, the unit's output voltage or output current control loops should be adjusted to provide stable operation. For HFSM regulators, the gain-crossover bandwidth (“GCB”) should be less than one half the unit's switching frequency. In practical terms, GCB is normally well below 10 kHz.

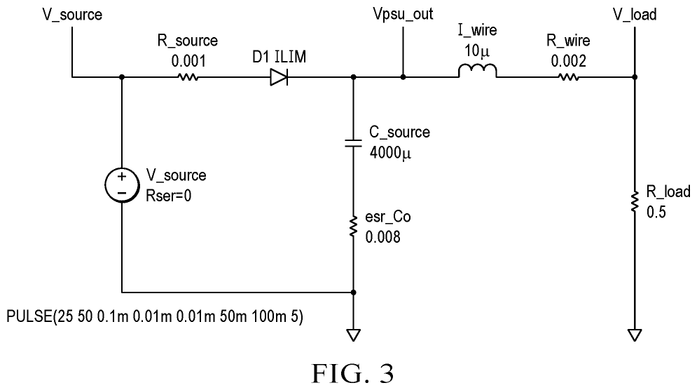

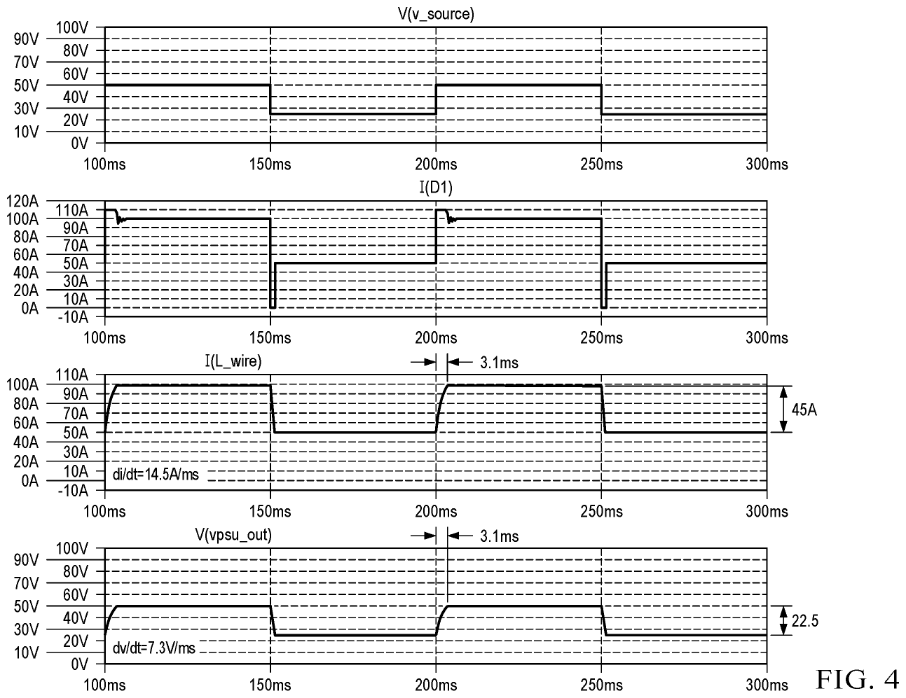

Output capacitors and the control loop's GCB, along with the converter's over-current protection (“OCP”) circuits limit the delivered slew rate. The OCP circuit limits the amount of charging current available to the capacitor in a program-up situation. For example, with reference to FIGS. 3 and 4, consider the above-mentioned unit. Assuming the unit's over-current protection circuit limits maximum current to 110% of rated value=110 A, if the output voltage is programmed to change, for example, from 25 V to 50 V, with a resistive load that results in 100 A of load current at 50 V, the output capacitor limits pulse current di/dt to 14.5 A/ms (see FIG. 4).

FIG. 3 illustrates a simplified circuit representation 300 of portions of an ac-dc power supply with a pulsed output current and FIG. 4 illustrates graphical representations of an operation thereof. FIG. 3 illustrates circuit parasitic elements such as input voltage source resistance R_source from a source of electrical power V_source, the equivalent series resistance (esr_Co) of the source capacitor (C_source), and an output wire resistance “R_wire.” FIG. 3 also illustrates circuit inductance L_wire that limits pulsed changes of output voltage and output load current. The slew rate of the output voltage Vpsu_out is 7.3 V/ms, which dominates the delivered current pulse slew rate (see FIG. 4).

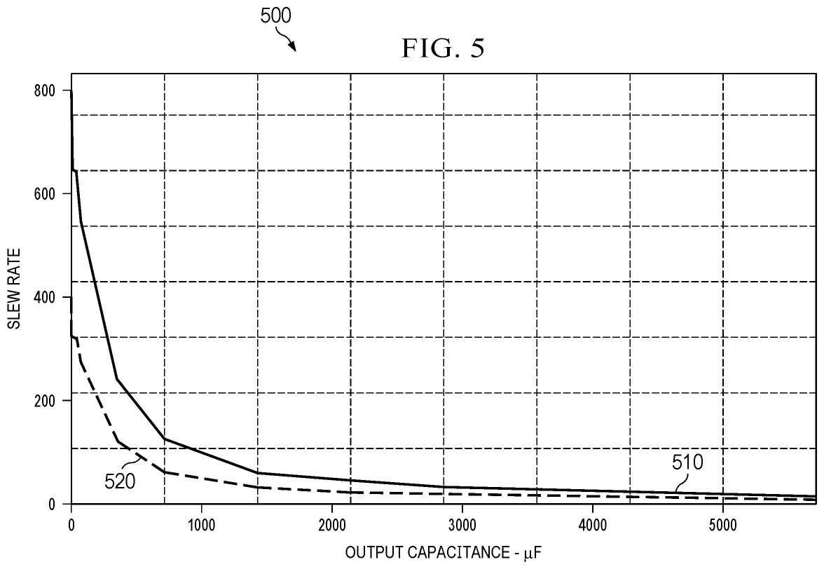

Turning now to FIG. 5, illustrated is a graphical representation 500 of an example slew rate of an output current 510 in amperes per milliseconds (“A/ms”) and output voltage 520 in volts per milliseconds (“V/ms”) versus capacitance of the output capacitor (in microfarads (“μF”)). If the output capacitor is decreased, the slew rate increases, but of course, output ripple voltage also increases. As shown in FIG. 5, a sufficiently small output capacitance should be chosen before an appreciable impact on slew rate is observable. Thus, conventional ac-dc power supply designs are not able to support ultra-high output current slew rates.

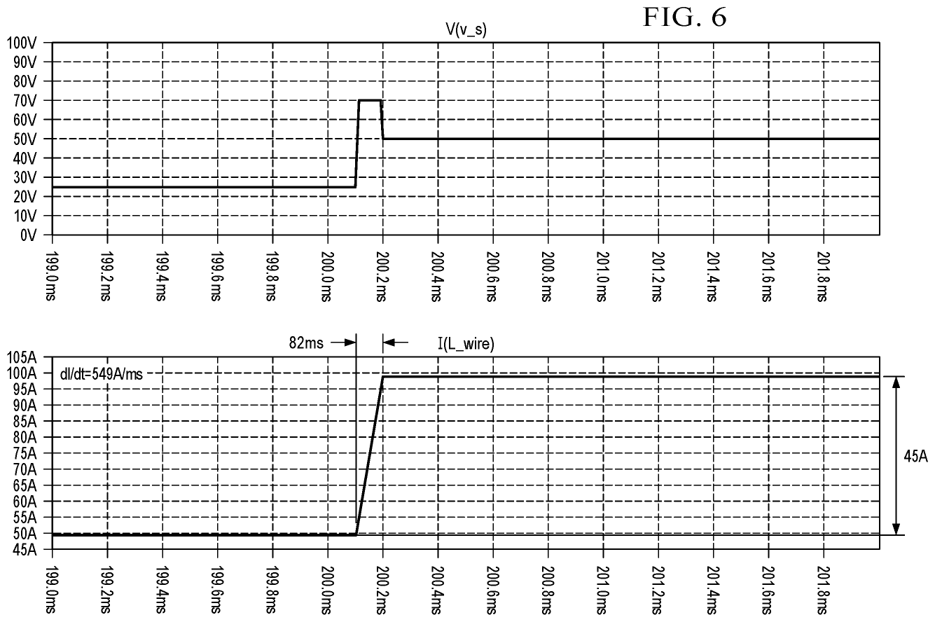

Another method available to help improve slew rate is to temporarily increase output voltage during the current rise time. For example, with an output capacitance of 125 μF (1.3 μF per ampere), di/dt without any boost voltage is 409 A/ms. If a 20 volt boost is added during the ramp up time, di/dt can be improved by 34% to 549 A/ms as illustrated in FIG. 6.

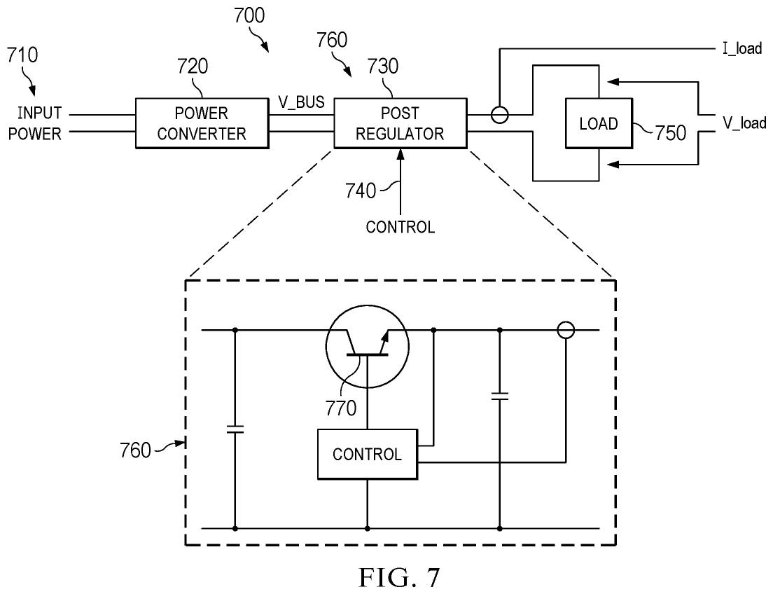

Turning now to FIG. 7, illustrated is a block diagram of an example power system 700 capable of operating from ac input power and delivering a high output voltage with high current slew rates in support of pulsed dc output currents in either a unipolar or bipolar format. Output current slew rates can exceed 5,000 amperes per millisecond. The power system includes a power converter 720 coupled to a source of electrical power 710 and a post regulator 730 with an input coupled to an output of the power converter 720. The post regulator 730 is often a transistor-based linear pass regulator. A voltage V_load and current I_load delivered to load 750 are monitored and transistor conduction is controlled in real time by a control signal 740 to optimize delivery of pulsed output current and/or pulsed output voltage. A simplified circuit structure of the post regulator 740 is illustrated by the circuit diagram 760.

The input voltage to the post regulator 730 is usually maintained at a constant level above the required load current sustaining voltage to aid in overcoming any load connection inductance during a current pulse rise time. In the example illustrated in FIG. 7, the pass transistor 770 in the post regulator 730 would likely be made up of multiple devices operating in parallel (e.g., a transistor circuit). Likewise, the control bandwidth of the post regulator 730 will have to be high enough to respond quickly to changes in current demand as dictated by the control input.

Depending on design parameters, power in the pass transistor 770 in the post regulator 730 can cause issues with forward biased safe operating area of the pass transistor 770, as well as repetitive thermal cycling effects impacting long term reliability. It is tempting to allow transistor junction temperature to approach its rated value during these excursions, but reliability theory teaches this will have a detrimental effect on expected life of the pass transistor 770 due to the repeated mechanical stress imparted to the die and package due to thermal expansion and contraction. When these parameters are taken into consideration very often the linear pass regulator becomes economically and volume burdensome to the end design. This topology places a heavy burden on the pass transistor(s) 770 as it must block the difference between the ac-dc power converter output voltage (a bus voltage V_bus) and the load voltage V_load while also passing all the load current I_load.

In an example embodiment, the power system 700 is configurable for delivering current precision and accuracy approaching 100 parts per million (“ppm”). The power system 700 can be readily configured for operating voltages between zero and 1000 Vdc. The power system 700 can be configured to provide high current slew rates in the presence of output cable inductance in series with the load. The power system 700 is constructed employing a high frequency switch-mode post regulator 730 featuring hysteretic current control. The post regulator 730 can be realized in blocks that are parallel compatible. The power system 700 can be configured to utilize either air or liquid cooling for a particular application.

In an embodiment, the power system 700 can incorporate an onboard control interface. The onboard control interface can be configured to communicate and interact with a host system through either analog, discrete digital, or serial digital communication processes. The onboard control interface generates a control signal 740 that can store and implement operational routines as programmed by the host system. The onboard controller can provide near real-time system operational status information with very low latency. An approach to solving the problem of increasing slew rate includes adding a post regulator 730 between the output of the ac-dc power converter 720 and the load 750, and to temporarily and controllably increase the voltage produced by the power converter 720 in response to a signal generated by a host system on a host interface.

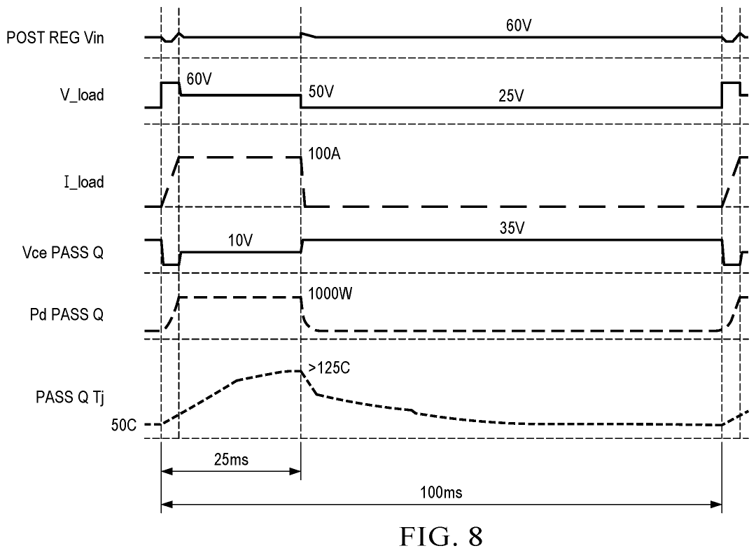

FIG. 8 illustrates waveforms for the post regulator produced by a power system during a current pulse in a design for a 1 kHz, pulsed 100 A current delivered from a 60 V_source. Illustrated by the waveforms in FIG. 8 are post regulator input voltage Vin (also referred to as a bus voltage V_bus), load voltage V_load, load current I_load, the collector-to-emitter voltage of the pass transistor Vce, power dissipation in the pass transistor Pd, and the pass transistor junction temperature Tj. Also shown in FIG. 8 is a brief increase in the load voltage V_load to enable a rapid slew rate of the output current (the load current I_load) of the power system. In an embodiment, the brief increase in the load current I_load with a high slew rate is provided by a controlled level of increase and duration of the load voltage V_load to enable the rapid slew rate of the output current (the load current I_load) without substantial overshoot or undershoot. The load current I_load in this illustration rapidly increases to 100 amperes with no overshoot.

The following post regulator design requirements are preferable. One prerequisite is the ability to support high pulse currents, e.g., delivered peak power in the 10's of kilowatts. Another prerequisite is the ability to support input overhead voltage to aid in overcoming lead inductance during pulse rise time. A third is that the control bandwidth should be high enough to support required pulse repetition frequency. There should be sufficiently small output capacitance to support fast rise times (<5 μF/A). (“microfarads per ampere”). Careful management should be provided for repetitive peak semiconductor power and junction temperature to assure long-term reliability. Given these considerations, post regulator solutions have been developed as described herein based on a high frequency switch-mode technology.

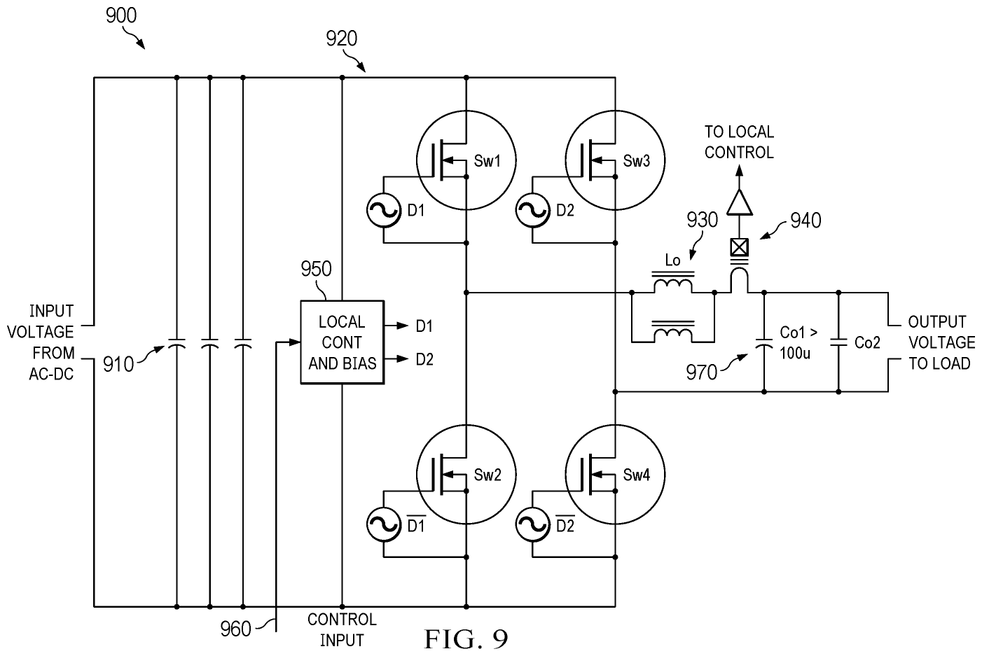

Turning now to FIG. 9, illustrated is a simplified schematic drawing of a high-frequency switch-mode power converter 900 designed to support 60V/30 A output with temporary increases in input voltages up to, for instance, 100 V. The power converter 900 is built, without limitation, around a synchronous buck topology operating at a switching frequency around 200 kHz at full load. The power converter 900 also includes hysteretic control topology that varies the switching frequency in response to output load changes.

An ac input voltage to the power converter 900 is coupled to input capacitors 910 to supply a dc voltage on a dc power bus 920 to power switches Sw1, Sw2, Sw3, Sw4. A switched voltage produced by the power switches Sw1, Sw2, Sw3, Sw4 is coupled to an output inductor 930 that are wired in series with current-sensing circuit element 940. The output of the current-sensing circuit element 940 is coupled to a control input of a local control and bias circuit 950 (a controller). The local control and bias circuit 950 produces duty-cycle signals D1, D2 that respond to a control input 960 from an external source (not shown) to control the power switches Sw1, Sw2, Sw3 and Sw4. Signals complementary to the duty cycle signals D1, D2 are symbolically shown in the drawing with a bar over each of the duty cycle signals D1, D2. An additional feature of the power converter 900 is the ability to reverse polarity of the delivered output voltage via power switches Sw3, Sw4. These are modulated to set the output polarity as signaled by a host system.

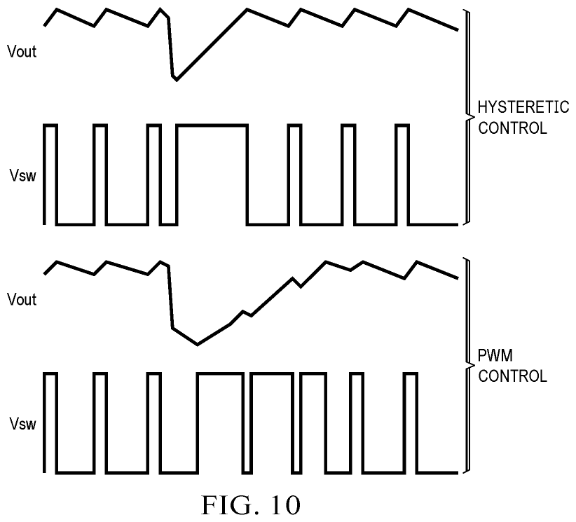

Turning now to FIG. 10, illustrated is a graphical representation that compares hysteretic control with pulse-width modulated (“PWM”) control. FIG. 10 illustrates the output voltages Vout and the duty cycle control waveforms Vsw for hysteretic and PWM control. Hysteretic control provides faster recovery of the output voltage Vout than PWM control. With hysteretic control, a power switch such as a metal-oxide semiconductor field-effect transistor (“MOSFET”) is turned on when a current level is at or below a minimum value. The power switch is turned off when the current level is at or above a maximum value. Hysteretic control provides excellent load current transient-response characteristics compared to the other types of controllers such as PWM voltage and current mode controllers with slower feedback loops.

Hysteretic control forces the power switch Sw1 illustrated in FIG. 9 to be on (and the power switch Sw2 to be off) continuously while output current is ramping up in response to a command from the host system. Hysteretic control provides optimal availability of input voltage to drive output current rise time.

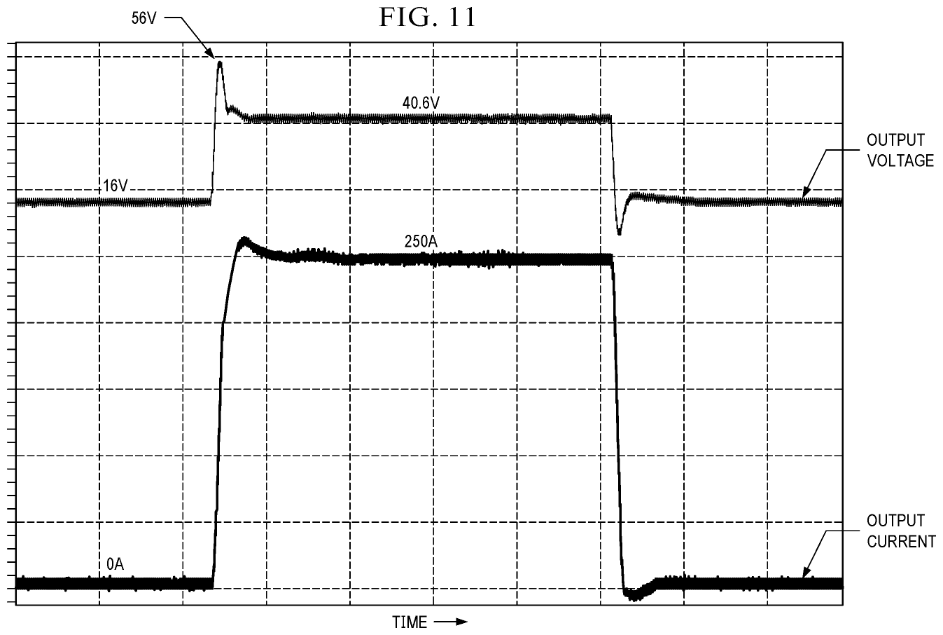

With an output capacitor (see output capacitors 970 in FIG. 9) less than 100 μF (providing ˜3 μF/A at 30 A) and high current control bandwidth, the power converter 900 supports extremely high output slew rates. Power converters similar to the power converter 900 depicted in FIG. 9 can be connected in parallel to support higher output power. For example, when eight of these assemblies are connected in parallel, slew rates on the order of 8,000 A/ms can be achieved in a semiconductor laser application, as illustrated in FIG. 11. FIG. 11 illustrates a pulsed 250 ampere output current produced by multiple converters operating in parallel, and the resulting output voltage.

Power conversion operating efficiency in the example design is greater than 97 percent (“%”), with power switch dissipation less than 6 W per part at full load. With conduction cooling employing a heat sink, this level of power dissipation in the power switch allows for modest switch temperature rise during pulsing operation, thereby limiting any impact on power switch life due to thermal cycling.

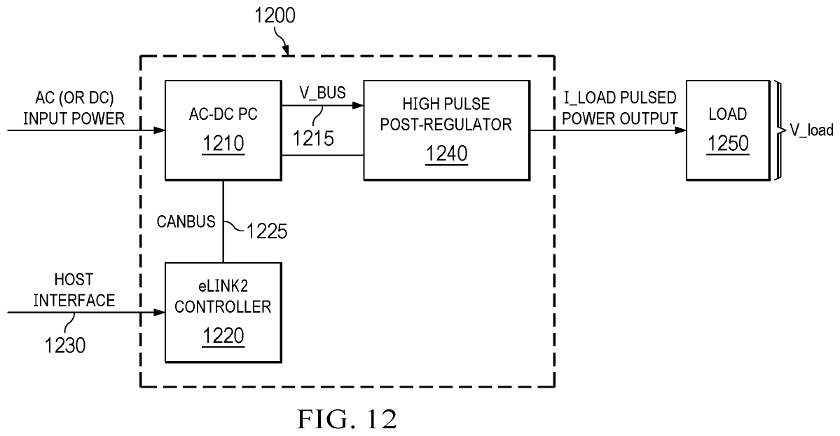

Turning now to a FIG. 12, illustrated is a block diagram of a high output current slew rate power system 1200. The power system 1200 is configured to provide output voltages up to 60 V and output currents up to 250 A.

The power system 1200 is formed with a front-end ac-dc power converter 1210 (“PC”) that is powered by 380-480 Vac, three-phase input power and occupies 2 U (referring to a modular height) of 19″ horizontal rack space and features liquid-cooling. The control interface can be realized through an eLink2 power system controller 1220 that communicates over a host interface 1230 through a discrete analog or high-speed serial digital bus, such as Ethernet.

The high frequency switch-mode power converter 1210 is configured to produce an output voltage (also referred to as a bus voltage Vbus) on an output bus 1215 controlled by a signal over the host interface 1230 that is generated by a host system (responsive to a control signal 1225 from the eLink2 power system controller 1220). The high frequency switch-mode power converter 1210 supplies dc power to a high pulse, post-regulator 1240 that produces a pulsed power output (including an output or load voltage V_load and an output or load current I_load) that is supplied to a load 1250. The post regulator 1240 has an input coupled to an output of the switch-mode power converter 1210 and is configured to produce the output voltage V_load controlled over the host interface 1230 (also responsive to a control signal 1225 from the eLink2 power system controller 1220). The host interface 1230 is employed to temporarily boost an output voltage V_bus, V_load of the switch-mode power converter 1210 and the post regulator 1240 for a period of time to enhance slewing of an output current I_load of the post regulator 1240 from a first level (e.g., a lower level) to a second level (e.g., a higher level) or vice versa.

The output voltage V_bus of the power converter 1210 is controlled by the e-Link2 power system controller 1220 that receives an input over the host interface 1230. The e-Link2 power system controller 1220, in addition to controlling the bus voltage V_bus of the power converter 1210, also controls the output voltage V_load of the high pulse post-regulator 1240. The e-Limk2 power system controller 1220 controls the power converter 1210 and high pulse post-regulator 1220 by controlling the respective switches thereof (see, e.g., power switches Sw1, Sw2, Sw3, Sw4 illustrated in FIG. 9 and switching circuit 770 illustrated in FIG. 7).

Thus, as introduced herein and with continuing reference to the FIGUREs herein, a post regulator (1240) for use with a power system (1200) includes a power converter (1210) configured to produce a bus voltage (V_bus) on an output bus (1215). The post regulator (1240) includes at least one switch (770) such as a transistor circuit (e.g., including a plurality of transistors) coupled to the output bus (1215) of the power converter (1210), and further includes a controller (1220) configured to receive the bus voltage (V_bus) and control the transistor circuit (770, see FIG. 7) to alter an output voltage (V_load) of the post regulator (1240) for a period of time to enhance a slew rate of an output current (I_load) and/or the output voltage (V_load) of the post regulator (1240) from a first level to a second level.

In an embodiment, the controller (1220) is configured to control the transistor circuit (770) to boost the output voltage (V_load) of the post regulator (1240) for the period of time to enhance (e.g., increase) a slew rate of the output current (I_load) and/or the output voltage (V_load) of the post regulator (1240) from the first level to the second level. In an embodiment, the controller (1220) is configured to control the transistor circuit (770) to reduce the output voltage (V_load) of the post regulator (1240) for the period of time to enhance the slew rate of the output current (I_load) and/or the output voltage (V_load) of the post regulator (1240) from the second level to the first level.

In an embodiment, a level of the alteration of the output voltage (V_load) of the post regulator (1240) and the period of time are selected to accelerate transitioning the output current (I_load) and/or the output voltage (V_load) from the first level to the second level. In an embodiment, the controller (1220) is configured to control the transistor circuit (770) responsive to a control signal (1230) from a host system.

As introduced herein, a power system (1200) includes a power converter (1210) configured to produce a bus voltage (V_bus) on an output bus (1215) in response to a first control signal (1225) from a power system controller 1220 (responsive to a signal (1230) from a host system). The power system also includes a post regulator (1240) coupled to the power converter (1210). The post regulator (1240) includes a switches such as a transistor circuit (e.g., 770, including a plurality of transistors) coupled to the output bus (1215) of the power converter (1210), and a controller (1220) configured to receive the bus voltage (V_bus) and control the transistor circuit (770) to alter an output voltage (V_load) of the post regulator (1240) for a period of time to enhance a slew rate of an output current (I_load) and/or the output voltage (V_load) of the post regulator (1240) from a first level to a second level.

In an embodiment, the controller (1220) is configured to control the transistor circuit (770) to boost the output voltage (V_load) of the post regulator (1240) for the period of time to enhance (e.g., increase) the slew rate of the output current (I_load) and/or the output voltage (V_load) of the post regulator (1240) from the first level to the second level. In an embodiment, the controller (1220) is further configured to control the transistor circuit (770) to reduce the output voltage (V_load) of the post regulator (1240) for a period of time to enhance the slew rate of the output current (I_load) and/or the output voltage (V_load) of the post regulator (1240) from the second level to the first level.

In an embodiment, a level of the alteration of the output voltage (V_load) of the post regulator (1240) and the period of time are selected to accelerate transitioning the output current (I_load) and/or the output voltage (V_load) from the first level to the second level. In an embodiment, the controller (1240) is configured to control the transistor circuit (770) responsive to a second control signal (1230) from the host system. In an embodiment, the power converter (1210) is an alternating-current to direct-current power converter.

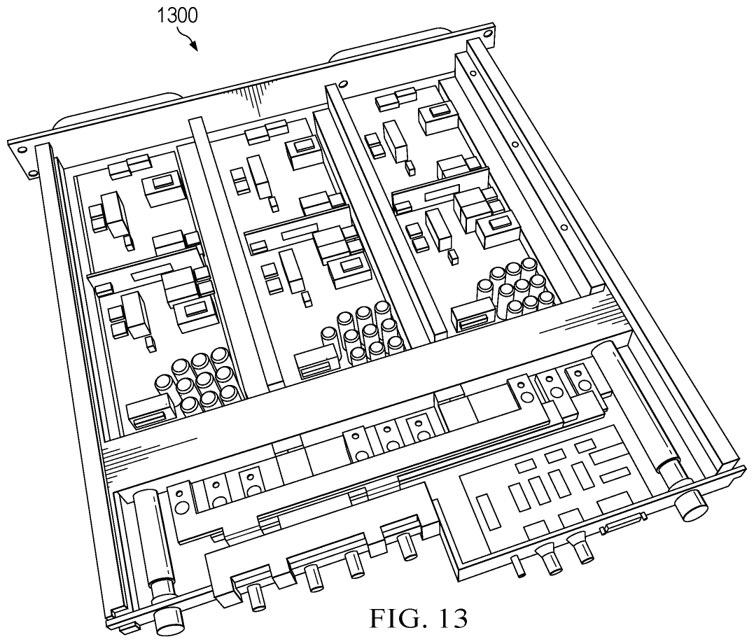

Various possibilities are contemplated herein for packaging of the power converters. For example, FIG. 13 illustrates an image of a monolithic implementation 1300 for a liquid-cooled, 80 V input/output unit that supports output currents up to 250 A. Likewise, a modularized post regulator approach can be constructed as introduced herein.

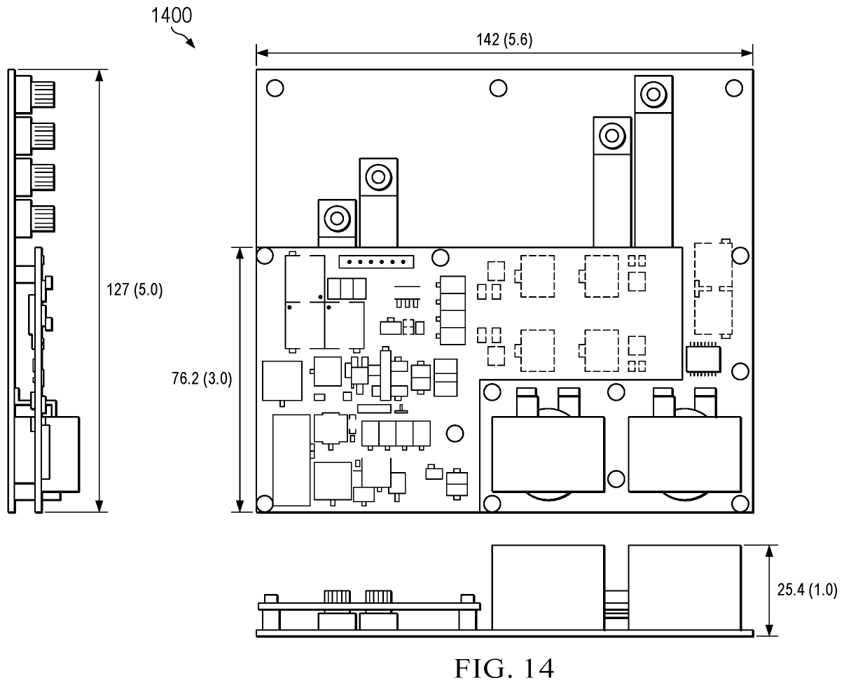

FIG. 14 provides an image of a 60 V/30 A assembly 1400 that can be paralleled with other like units to support currents to hundreds of amperes. The modularized converter in FIG. 14 is designed with a metal base plate that can interface to either a liquid or air-cooled heat sink. Power conversion efficiency is greater than 97% at full power, generating less than 50 W of heat when delivering 55 V at 30 A.

Other examples of the scalable nature of this technology have been constructed including:
a 3.33 kW air-cooled post regulator module,
a 10 kW air-cooled high slew rate system, and
a 2.2 kW air-cooled high slew rate power module.

Thus, a high frequency switch mode technology has been introduced that provides an improved ac to pulsed dc output power system. The power system can provide output current slew rates greater than 5,000 A/ms while also managing component reliability considerations resulting from thermal fatigue and safe operating conditions.

Although the embodiments and its advantages have been described in detail, it should be understood that various changes, substitutions, and alterations can be made herein without departing from the spirit and scope thereof as defined by the appended claims. For example, many of the features and functions discussed above can be implemented in software, hardware, or firmware, or a combination thereof. Also, many of the features, functions, and steps of operating the same can be reordered, omitted, added, etc., and still fall within the broad scope of the various embodiments.

Moreover, the scope of the various embodiments is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein can be utilized as well. Accordingly, the appended claims are intended to include within their scope such processes, machines, manufacture, compositions of matter, means, methods, or steps.

1. A post regulator for use with a power system including a power converter configured to produce a bus voltage on an output bus, comprising:
a transistor circuit coupled to said output bus of said power converter; and
a controller configured to receive said bus voltage and control said transistor circuit to alter an output voltage of said post regulator for a period of time to enhance a slew rate of an output current or said output voltage of said post regulator from a first level to a second level.

2. The post regulator as recited in claim 1 wherein said transistor circuit comprises a plurality of transistors.

3. The post regulator as recited in claim 1 wherein said controller is configured to control said transistor circuit to boost said output voltage of said post regulator for said period of time to enhance said slew rate of said output current or said output voltage of said post regulator from said first level to said second level.

4. The post regulator as recited in claim 3 wherein said controller is configured to control said transistor circuit to reduce said output voltage of said post regulator for a period of time to enhance said slew rate of said output current or said output voltage of said post regulator from said second level to said first level.

5. The post regulator as recited in claim 1 wherein a level of said alteration of said output voltage of said post regulator and said period of time are selected to accelerate transitioning said output current or said output voltage from said first level to said second level.

6. The post regulator as recited in claim 1 wherein said controller is configured to control said transistor circuit responsive to a control signal from a host system.

7. A power system, comprising:
a power converter configured to produce a bus voltage on an output bus in response to a first control signal generated by a host system; and
a post regulator coupled to said power converter, including a transistor circuit coupled to said output bus of said power converter, and
a controller configured to receive said bus voltage and control said transistor circuit to alter an output voltage of said post regulator for a period of time to enhance a slew rate of an output current or said output voltage of said post regulator from a first level to a second level.

8. The power system as recited in claim 7 wherein said transistor circuit comprises a plurality of transistors.

9. The power system as recited in claim 7 wherein said controller is configured to control said transistor circuit to boost said output voltage of said post regulator for said period of time to increase said slew rate of said output current or said output voltage of said post regulator from said first level to said second level.

10. The power system as recited in claim 9 wherein said controller is further configured to control said transistor circuit to reduce said output voltage of said post regulator for a period of time to reduce said slew rate of said output current or said output voltage of said post regulator from said second level to said first level.

11. The power system as recited in claim 7 wherein a level of said alteration of said output voltage of said post regulator and said period of time are selected to accelerate transitioning said output current or said output voltage from said first level to said second level.

12. The power system as recited in claim 7 wherein said controller is configured to control said transistor circuit responsive to a second control signal from said host system.

13. The power system as recited in claim 7 wherein said power converter is an alternating current to direct current power converter.

14. A method of operating a power system, comprising:
producing a bus voltage on an output bus of a power converter in response to a first control signal generated by a host system;
receiving said bus voltage at a post regulator; and
controlling a transistor circuit of said post regulator to alter an output voltage of said post regulator for a period of time to enhance a slew rate of an output current or said output voltage of said post regulator from a first level to a second level.

15. The method as recited in claim 14 wherein said transistor circuit comprises a plurality of transistors.

16. The method as recited in claim 14 wherein said controlling comprises controlling said transistor circuit to boost said output voltage of said post regulator for said period of time to enhance said slew rate of said output current or said output voltage of said post regulator from said first level to said second level.

17. The method as recited in claim 16 wherein said controlling comprises controlling said transistor circuit to reduce said output voltage of said post regulator for a period of time to enhance said slew rate of said output current or said output voltage of said post regulator from said second level to said first level.

18. The method as recited in claim 14 wherein a level of said alteration of said output voltage of said post regulator and said period of time are selected to accelerate transitioning said output current or said output voltage from said first level to said second level.

19. The method as recited in claim 14 wherein said controlling said transistor circuit is responsive to a second control signal from said host system.

20. The method as recited in claim 14 wherein said power converter is an alternating current to direct current power converter.
